(19) United States
(12) Patent Application Publication
(10) Pub. No.: US 2004/0243910 A1
(43) Pub. Date: Dec. 2, 2004

(54) Packet data recovery system

(76) Inventor: Gordon R. McLeod, Linlithgow (GB)

Correspondence Address: Timothy N. Trop, TROP, PRUNER & HU, P.C., STE 100, 8554 KATY FWY, HOUSTON, TX, 77024-1841, US

(21) Appl. No.: 10/448,008

(22) Filed: May 29, 2003

(51) Int. Cl. G11C 29/00

(52) U.S. Cl. 714/765

(57) ABSTRACT

The technique in accordance with the invention includes receiving data units from a bus. Each data unit is received from the bus at a different time. The method includes, for each data unit, concurrently generating a first indication of a content of the data unit and a second indication of a content of one of the data units received from the bus prior to the data unit.

### BACKGROUND

The invention generally relates to a packet data recovery system.

Bits of data typically are communicated over a bus via one or more data signals. In this manner, each data line of the bus communicates a particular data signal, and different time slots of this data signal indicates different bits of data. The bus typically includes a clock line that communicates a clock signal for purposes of indicating the time positions of the bits in the data signals so that the bits may be recovered from the data signals.

The data that is communicated across the bus may be organized in packets for purposes of tracking the data, identifying certain data with certain applications or data flows, etc. Different techniques may be used to indicate the boundaries (i.e., the beginning and ending) of each packet. For example, the beginning and end of each packet may be indicated by the selective assertion of one or more control signals on the bus. Alternatively, the beginning and end of each packet may be indicated by control data that is dispersed among the packet data. The latter approach typically is called an in-band signaling scheme.

With the in-band signaling scheme, circuitry at the receiver sorts the packet data from the control data and determines which control data indicates the beginning of a particular packet, which control data indicates the end of a particular packet, etc. This task may present challenges, however, because the bus communication protocol, or standard, that governs the in-band signaling scheme may not specify criteria to make the sequence at which packet and/or control data appears on the bus predictable. For example, the standard may not specify the length (in bytes or words) of the packets, the spacing of the control words, the inter-packet gaps, etc. The standard may be written in this fashion to provide flexibility in permitting the use of the bus with a variety of different packet protocols. However, the circuitry that recovers packet data from such a bus may be quite complex, and as a result, this circuitry may consume a considerable amount of die area, take a significant amount of time to decode the captured data and may generally increase the cost of development of a system that uses this bus.

As an example, a bus standard that provides such flexibility is the System Packet Interface Level 4 Phase 2 (SPI-4 Phase 2) bus standard specification, such as version 2000.088.4, available from the Optical Internetworking Forum (OIF), located at 39355 California Street, Suite 307, Fremont, Calif. 94538. The SPI-4 Phase 2 bus is a 16-bit wide 400 MHz double data rate telecommunications bus that may be used to exchange packet level information between link and physical layers of a particular network protocol. For purposes of ensuring that the SPI-4 bus is compatible with a variety of packet protocols, the SPI-4 Phase 2 bus standard places no restrictions on the spacing of control characters or on the size or spacing of the packets. Circuitry that recovers data from the SPI-4 Phase 2 bus may encounter the challenges discussed above.

Thus, there is a continuing need for an arrangement and/or technique to address one or more of the problems that are stated above as well as possibly address one or more other problems that are not set forth above.

### BRIEF DESCRIPTION OF THE DRAWING

FIG. 1 is a block diagram of a packet data recovery system according to an embodiment of the invention.

FIGS. 2, 3, 4, 5 and 6 are waveforms illustrating the communication of data over a bus of FIG. 1 according to an embodiment of the invention.

FIG. 7 is a block diagram of a data analyzer of the system of FIG. 1 according to an embodiment of the invention.

FIG. 8 is a schematic diagram of an error monitoring circuit of the data analyzer of FIG. 7 according to an embodiment of the invention.

FIG. 9 is a schematic diagram of a data windowing circuit of the data analyzer of FIG. 7 according to an embodiment of the invention.

FIG. 10 is a table illustrating operation of a control word filter of the data analyzer of FIG. 7 according to an embodiment of the invention.

FIGS. 11 and 12 are schematic diagrams that depict different portions of control deinterleave logic of the data analyzer of FIG. 7 according to an embodiment of the invention.

FIG. 13 is a block diagram of a switching system according to an embodiment of the invention.

### DETAILED DESCRIPTION

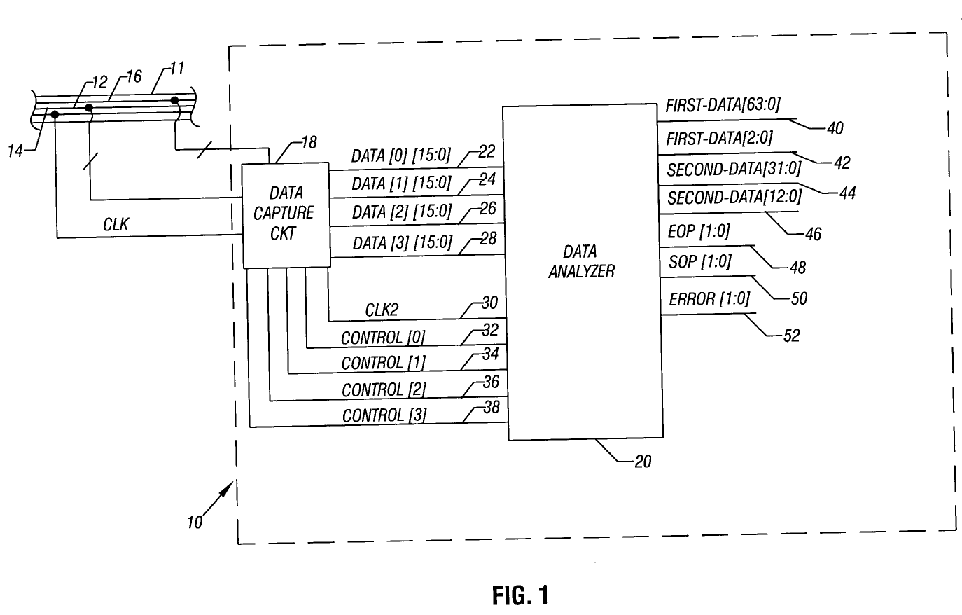

Referring to FIG. 1, an embodiment 10 of a packet data recovery system in accordance with the invention includes a data capture circuit 18 and a data analyzer 20. The data capture circuit 18 is coupled to a bus 11 for purposes of recovering, or capturing, data that is communicated across the bus 11. In some embodiments of the invention, the data capture circuit 18 receives signals from data lines 12 of the bus 11 so that the data capture circuit 18 may capture data from the bus 11 in synchronization with a clock signal (called CLK) that appears on a clock line 14 of the bus 11. As described below, the data capture circuit 18 communicates the captured data to a data analyzer 20 that generates signals that identify the content of the captured data, including signals that identify which bytes or words constitute packet data. More specifically, in some embodiments of the invention, the data analyzer 20 generates signals that associate certain captured data to particular packets, associate certain captured data to being certain control words, identify certain captured data as being invalid, etc.

Data is received from the bus 11 in blocks, herein called “data units,” of a certain size (four words, for example). Each data unit is received in a different time slot (also referred to herein as “a time”); and each of these time slots may be synchronized to an edge of the CLK clock signal. For example, in some embodiments of the invention, a set of four words of data (i.e., a “data unit”) may be received by the data capture circuit 18 in synchronization with each edge of the CLK clock signal. Thus, for this example, each set of four words, or data unit, is received in a different time slot.

Due to the protocol that may govern the communication of data over the bus 11, a particular data unit that is received during a particular time slot may contain data that is associated with more than one packet. More particularly, the communication of data over the bus 11 may be governed by a bus standard that does not specify a predictable packet sequence, such as the packet length (in bytes or words), the spacing of the control words used in in-band signaling, inter-packet gaps, etc.

As a more specific example, a data unit of four words (for this example) may include a packet control word and a packet data word that are associated with one packet and two packet data words from another packet. Therefore, for this example, the data for particular packets is received in more than one time slot, thereby creating potential “corner cases” for the data analyzer 20 to consider when generating the signals that identify the content of the captured data, as the data analyzer 20 indicates which data belongs to which packet.

In some embodiments of the invention, for purposes of minimizing the occurrence of these corner cases, the data analyzer 20 uses a data window to identify data that was captured in two time slots. The data analyzer 20 concurrently processes data in the window to generate an indication of data content within these two time slots. In some embodiments of the invention, the data analyzer 20 concurrently generates indications of data content within these two time slots at the same frequency at which data is captured from the bus 11. As described below, because the data analyzer 20 simultaneously analyzes data that is received in multiple time slots, the above-referenced “corner conditions” are minimized, a result that simplifies the design of the analyzer 20.

As a more specific example, in some embodiments of the invention, the data lines 12 may, in each time slot, communicate a data unit that is formed from four, sixteen bit words. It is understood that a particular data unit may include more or less than four words, depending on the particular embodiment of the invention. However, for purposes of simplifying the discussion of the data analyzer 20, it is assumed below that each data unit is four words, (i.e., the width of the data path of the bus 11 is sixty-four bits).

The data capture circuit 18 uses the CLK signal to synchronize the capture of the data units from the bus 11. More specifically, in some embodiments of the invention, the data capture circuit 18 may synchronize the capture of data units from the bus 11 pursuant to a double data rate (DDR) clocking scheme in which the data capture circuit 18 captures a data unit on each edge (positive going or negating going edge) of the CLK clock signal (provided by the clock line 14). Various other arrangements are possible for communicating and synchronizing the transmission of data across the bus 11, depending on the particular embodiment of the invention. However, the DDR clocking scheme is assumed below for purposes of simplifying the discussions of the data capture circuit 18 and the data analyzer 20.

In some embodiments of the invention, the data capture circuit 18 provides indications of each captured data unit to the data analyzer 20 via signals that appear on output terminals 22, 24, 26 and 28 (of the data capture circuit 18). In some embodiments of the invention, these signals are updated at a frequency near or equal to the frequency of the CLK signal. More particularly, in some embodiments of the invention, the data terminals 22 indicate a first word of a particular captured data unit via signals called DATA[0][15:0]; the data terminals 24 indicate a second word of the data unit indicated by signals called DATA[1][15:0]; the data terminals 26 indicate a third word of the data unit via signals called DATA[2][15:0]; and the data terminals 28 indicate a fourth word of the data unit via signals called DATA[3][15:0].

The updates to these signals occur in synchronization with a CLK2 signal that appears on an output terminal 30 (of the data capture circuit 18). In some embodiments of the invention, updates to the output terminals 22-28 (to indicate another captured data unit) occur in synchronization with the positive going edges of the CLK2 signal, and the CLK2 signal has a frequency that is twice the frequency as the CLK signal. Therefore, because each data unit is captured on both edges of the CLK signal, the signals appearing on the terminals 22-28 are updated at the same frequency at which the data units are captured, in some embodiments of the invention. Other variations are possible.

Thus, in accordance with some embodiments of the invention, on each cycle of the CLK2 signal, the data capture circuit 18 changes the signal states on the DATA[0][15:0], DATA[1][15:0], DATA[2][15:0] and DATA[3][15:0] signals to indicate another data unit that was captured from the bus 11.

In addition to the clock and data signals, the bus 11 may also communicate, in some embodiments of the invention, various control signals via control lines 16 of the bus 11. More specifically, in some embodiments of the invention, the bus 11 may include four such control lines 16, each of which is associated with a particular word of data on the bus 11 to indicate whether the word is a control word. Therefore, when a particular word of a data unit is a control word, the appropriate line 16 may be asserted (driven high, for example) to indicate the control word. The data capture circuit 18 has four output terminals 32, 34, 36 and 38 that communicate signals called CONTROL[0], CONTROL[1], CONTROL[2] and CONTROL[3], respectively, to indicate whether a particular word (appearing on the data terminals 22-28) is a control word. For example, if the word that is indicated by the DATA[1][15:0] signals is a control word, then the data capture circuit 18 asserts (drives high, for example) the CONTROL[1] signal; and otherwise, the data capture circuit 18 de-asserts (drives low, for example) the CONTROL[1] signal.

Thus, on each cycle of the CLK2 signal, the data capture circuit 18 indicates four data words and identifies the words (if any) that are control words. The function of the data analyzer 20, in turn, is to generate indications identifying the content of these four words, i.e., identify which (if any) of these four data words are control words, identify which (if any) of the four words of data belong to a first packet, identify which (if any) of these four words belong to a second packet, and identify which (if any) of the four words are valid/invalid. The data analyzer 20 also indicates which control words are end-of-packet and start-of-packet control words.

More specifically, in some embodiments of the invention, the data analyzer 20 provides signals called FIRST_DATA[63:0] that indicate up to four packet data words of a first packet of data that has been recovered from the bus 11. However, some of the words that are associated with the first packet may be control words and not packet data. To specifically identify the packet words and control words, the data analyzer 20 provides signals called FIRST_SIZE[2:0] that indicate the number of first packet words (i.e., the first packet data) that are indicated by the FIRST_DATA[63:0] signals. The first packet words that are indicated by the FIRST_DATA[63:0] signals are arranged in a least significant word first fashion. For example, if the FIRST_DATA[63:0] signals indicate three words of first packet data, then the three least significant words indicated via the FIRST_DATA[63:0] signals are packet data words, and the most significant word indicated by these signals is a control word. As another example, if the FIRST_SIZE[2:0] signals indicate two words of first packet data, then the two least significant words are first packet data, and the two most significant words indicated by the FIRST_DATA[63:0] signals are control words.

In some embodiments of the invention, the data analyzer 20 also provides signals called SECOND_DATA[31:0] that indicate packet data for a second packet. Unlike the FIRST_DATA[63:0] signals, the SECOND_DATA[31:0] signals indicate a maximum of two second packet words for the second packet. This is embodiment specific, and the SECOND_DATA signals may indicate up to a higher number (four, for example) of second packet words in other embodiments of the invention. However, for the embodiments described herein, the bus 11 may use a protocol in which data from the second packet is preceded by at least one word from the first packet and one control word from the first packet to terminate it. Thus, at most, the SECOND_DATA[31:0] signals may indicate up to two words.

For purposes of indicating how many of the SECOND_DATA[31:0] signals indicate packet data, the data analyzer 20 furnishes signals called SECOND_SIZE[1:0]. The SECOND_SIZE[1:0] signals indicate the number of second packet words that are indicated by the SECOND_DATA[31:0] signals in a fashion similar to how the FIRST_SIZE[2:0] signals identify first packet words in the FIRST_DATA[63:0] signals. Therefore, if the SECOND_SIZE[1:0] signals indicate one second packet data word, the least significant word (indicated by the SECOND_DATA[31:0] signals) indicates this second packet word, and the most significant word is a control word.

A control words, as its name implies, indicates control information. As examples, the control words include an end of packet control word to indicate the end of a particular packet and a start of packet control word to indicate the beginning of a particular packet. The data analyzer 20 furnishes signals (on output terminals 48) called EOP[1:0] that indicate the position in the FIRST_DATA[63:0] signals of an end-of-packet control word, and the data analyzer 20 furnishes signals (on output terminals 50) called SOP[1:0] that indicate the position in the FIRST_DATA[63:0] signals of a start-of-packet control word. Other variations and control words are possible.

The data analyzer 20 may furnish a variety of other signals and may receive additional input signals, according to different embodiments of the invention. Among these other signals, the data analyzer 20 may furnish ERROR[1:0] signals on terminals 52. The ERROR[1:0] signals identify one or more words (as indicated on the output terminals 22-28) in which errors have been detected.

In some embodiments of the invention, the bus 11 may operate pursuant to a bus standard, such as the System Packet Interface Level 4 Phase 2 (SPI-4 Phase 2) bus standard, such as version 2000.088.4, available from the Optical Internetworking Forum (OIF), located at 39355 California Street, Suite 307, Fremont, Calif. 94538. The SPI-4 Phase 2 bus is a 16-bit wide 400 MHz double data rate telecommunications bus that may be used to exchange packet level information between link and physical layers of a particular network protocol.

For purposes of quickly and efficiently capturing the data from the bus 11, in some embodiments of the invention, the data analyzer 20 uses combinatorial logic and a data capture window, described below. With this approach, in some embodiments of the invention, the data analyzer 20 does not use any state machines. This approach significantly reduces the potential complexity of the system 10, thereby conserving die space, reducing the overall cost of designing and implementing the system 10, improving system 10 speed and performance, etc.

Thus, in accordance with an embodiment of the invention, the system 10 provides combinatorial splitting of data from a multiple-word input bus 11. This data from the bus 11 contains words from multiple packets that the system 10 splits into separate busses for each packet, i.e., the FIRST_DATA[63:0] and SECOND_DATA[31:0] signals. Furthermore, in some embodiments of the invention, the system provides combinatorial removal of in-band control words and provides data steering to close any gaps in the data.

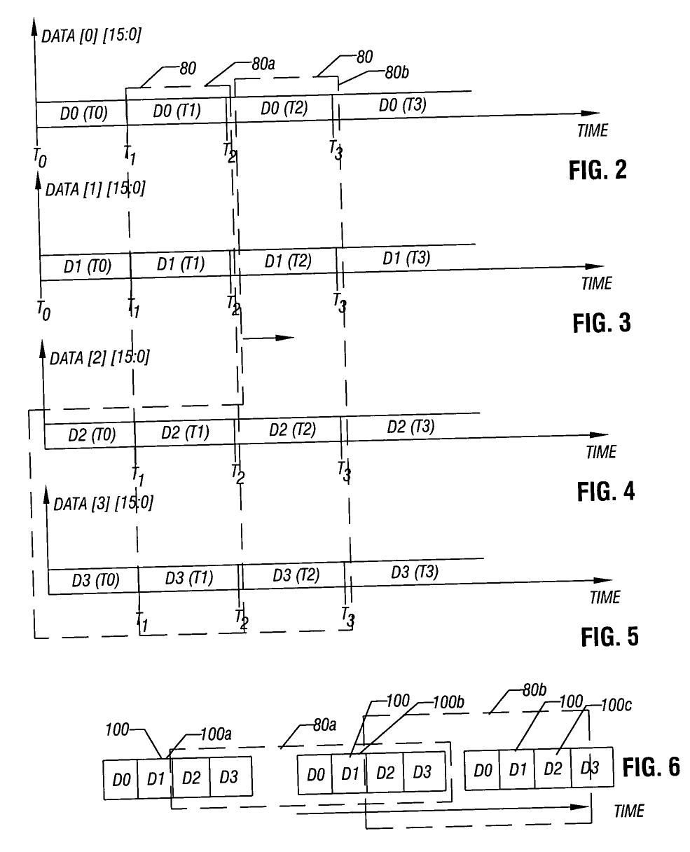

Referring to FIGS. 2, 3, 4 and 5, in some embodiments of the invention, the data analyzer 20 uses a data window 80 (data windows 80a and 80b, depicted as examples) to concurrently process the four current words of the current data unit that is indicated by the data capture circuit 18 (via the terminals 22-28 (FIG. 1)), and the two words that immediately preceded the current four words in the previously captured data unit. The data state captured by the window 80, in turn, permits the use of relatively noncomplex circuitry that is able to cope with all of the difficult corner cases that may occur relative to reading captured data from the bus 11 as being a single sixty-four bit input. For purposes of understanding the use of the window 80, FIG. 6 depicts three different data units 100a, 100b and 100c that are communicated across the bus 11 in different time slots (i.e., at different times). Each data unit 100 includes four words: D0, D1, D2 and D3, listed in order of significance. Thus, the captured order of the data represented by the data units 100a, 100b and 100 c is as follows (listed from most significant to least significant): D3, D2, D1 and D0 of the data unit 100c; D3, D2, D1 and D0, of the data unit 100b; and D3, D2, D1 and D0, of the data unit 100a.

The data analyzer 20 uses the window 80a for the scenario when the data unit 100a is the unit that was immediately previously indicated by the data capture circuit 18 and the data set 100b contains the words that are currently indicated by the data capture circuit 18. As shown, the data analyzer 20 uses the window 80a to identify six words: four words D0, D1, D2 and D3 of the data unit 100b and the two most significant words D2 and D3 of the data unit 100a.

As another example, the window 80b is used by the data analyzer 20 when the data unit 100c is the data unit currently being indicated by the data capture circuit 18, and the data unit 100b is the immediate previous data unit that was indicated by the data capture circuit 18. The data analyzer 20 uses the window 80b to capture all four words of the data unit 100c and the two most significant words (D3 and D2) from the previous data unit 100b.

FIGS. 2, 3, 4, 5 and 6 also depict the windows 80a and 80b. In this manner, FIG. 2 depicts the DATA[0][15:0] signals for time slots called T₀, T₁, T₂ and T₃; FIG. 3 depicts the DATA[1][15:0] signals for the T₀, T₁, T₂ and T₃ time sots; FIG. 4 depicts the DATA[2][15:0] signals for the T₀, T₁, T₂ and T₃ time slots; and FIG. 5 depicts the DATA[3][15:0] signals for the T₀, T₁, T₂ and T₃ time slots. Thus, as can be seen from these figures, during time T₁ time slot, the data capture circuit 18 indicates data words called DO(T₁), D1(T₁), D2(T₁) and D3(T₁). As shown, the data window 80a encompasses these words, as well as the words as D2(T₀) and D3(T₀), the previous two most significant words that were indicated by the data capture circuit 18 during the time slot T₀. Thus, the window 80 captures six words. As described below, the data analyzer 20 uses the words that are captured by the window 80 to form an input state from which the data analyzer generates its output signals.

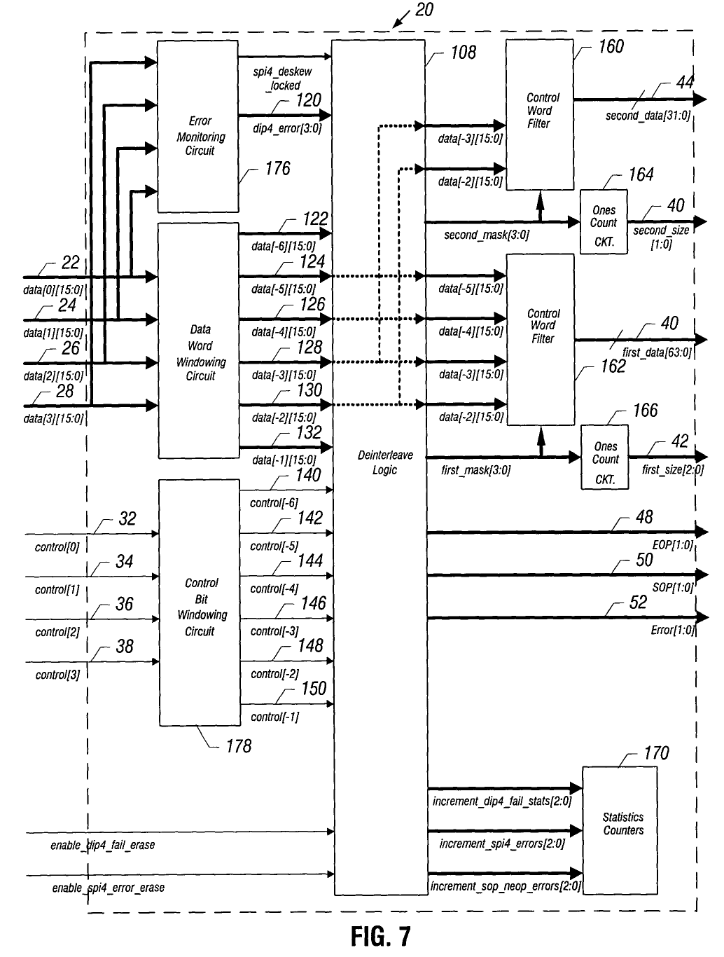

Referring to FIG. 7, for purposes of effectively creating the window 80, the data analyzer 20 includes a data word windowing circuit 110 that receives the DATA[0][15:0], DATA[1][15:0], DATA[2][15:0] and DATA[3][15:0] signals. The data word windowing circuit 110, in turn, indicates six words that are captured by the window 80. More specifically, the data word windowing circuit 110 provides signals called DATA[−1][15:0], DATA[−2][15:0], DATA[−3][15:0], DATA[−4][15:0], DATA[−5][15:0] and DATA[−6][15:0] on output terminals 132, 130, 128, 126, 124 and 122, respectively. As will become apparent below, the DATA[−1][15:0], DATA[−2][15:0], DATA[−3][15:0] and DATA[−4][15:0] signals indicate delayed (by one CLK cycle) versions of the DATA[3][15:0], DATA[2][15:0], DATA[1][15:0] and DATA[0][15:0] signals, respectively. The DATA[−5][15:0] and DATA[−6][15:0] signals, in turn, indicate the two most significant words that were previously indicated by the data capture circuit 18. Thus, the DATA[−5][15:0] signal indicates the previous word that was indicated by the DATA[3][15:0] signals, and the DATA[−6][15:0] signals indicate the word that was previously indicated by the DATA[2][15:0] signals. Thus, the data word windowing circuit 110 effectively provides the window 80 to capture four words from one data unit and the two most significant words of the preceding data unit. It is these words that are furnished to deinterleave circuit 108 of the data analyzer 20 for purposes of content identification.

In some embodiments of the invention, for each new window 80, the data analyzer 20 indicates the content of the words that are indicated by the DATA[−2][15:0], DATA[−3][15:0], DATA[−4][15:0] and DATA[−5][15:0] signals. Thus, for the example depicted in FIG. 6, for the window 80a, the data analyzer 20 concurrently indicates the content for the D0, D1, and D2 words (associated with the DATA[−4][15:0], DATA[−3][15:0] and DATA[−2][15:0] signals, respectively) of the data unit 100b and the content of the D3 word (associated with the DATA[−5][15:0] signals) of the data unit 100a.

The DATA[−1][15:0] signals allow the data analyzer 20 to look ahead by one cycle to see if the next word is an end-of-packet control word. In FIG. 6, for the exemplary window 80a, the next word is the D3 word of the data unit 100b. The DATA[−6][15:0] signals allow the data analyzer 20 to look behind by one cycle to see if the last word in the previous cycle was a start-of-packet control word. In FIG. 6, for the exemplary window 80a, the last word is the D2 word of the data unit 100a.

Referring to FIG. 7, the deinterleave logic 108 of the data analyzer 20 provides the DATA[−2][15:0], DATA[−3][15:0], DATA[−4][15:0] and DATA[−5][15:0] signals to a control word filter 162. The control word filter 162, as its name implies, filters the control words (if any) from these data signals to furnish the FIRST_DATA[63:0] signals. The control word filter 162 receives an indication of which of these words are control words via signals called FIRST_MASK[3:0] that are furnished by the deinterleave logic 108. For purposes of indicating the size of the packet data in the FIRST_DATA[63:0] signals, the data analyzer 120 includes a ones count circuit 166 that receives the FIRST_MASK[3:0] signals, counts the number of first packet words appearing the FIRST_DATA[63:0] signals, and produces the FIRST_SIZE[2:0] signals.

The data analyzer 20 also includes, in some embodiments of the invention, a control word filter 160 that provides the SECOND_DATA[31:0] signals in response to the DATA[−2][15:0] and DATA[−3][15:0] signals and signals called SECOND_MASK[3:0]. The SECOND_MASK[3:0] signals indicate which ones of the SECOND_DATA[31:0] signals are control signals, and thus, indicates which words to filter out from the DATA[−2][15:0] and DATA[−3][15:0] signals. A ones count circuit 164 counts the number of second packet words that appear in the SECOND_DATA[31:0] to furnish the SECOND_SIZE[1:0] signals.

Among its other features, in some embodiments of the invention, the data analysis circuit 20 includes statistics counters 170 that are coupled to the deinterleave logic 108. The data analyzer 20 also includes a control bit windowing circuit 178 that receives the CONTROL[0], CONTROL[1], CONTROL[2] and CONTROL[3] signals and furnishes signals called CONTROL[−1], CONTROL[−2], CONTROL[−3], CONTROL[−4], CONTROL[−5] and CONTROL[−6] at its output terminals 150, 148, 146, 144, 142 and 140, respectively. The control bit windowing circuit 178 operates in a similar manner to the data word windowing circuit 110, in that the circuit 178 captures the four current control states associated with the current data words and captures the two most significant previously transmitted control states. It is these control signals that the deinterleave logic 108 uses to generate the FIRST_MASK[3:0] and SECOND_MASK[3:0] signals.

In some embodiments of the invention, the data analysis circuit 20 also includes an error monitoring circuit 176 that performs parity checks on the DATA[0][15:0], DATA[1][15:0], DATA[2][15:0] and DATA[3][15:0] signals for purposes of monitoring the quality of incoming data. This may be particularly important in bus protocols, such as the SPI-4 Phase 2 protocol, that use dynamic deskewing of the double data rate input so that there are time slots in which input timing was not correctly adjusted, so incoming words may be invalid.

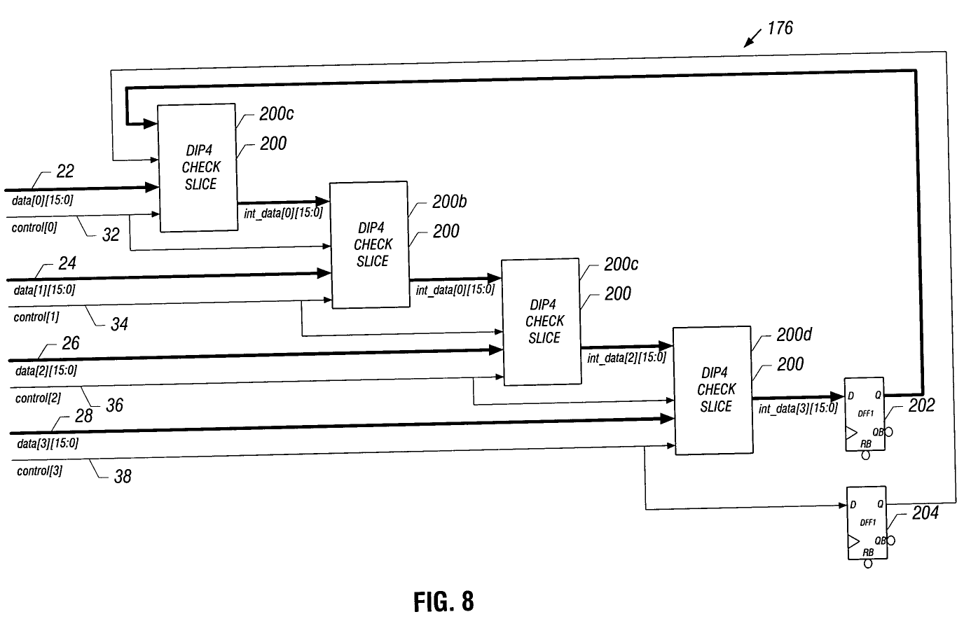

In some embodiments of the invention, the error monitoring circuit 176 may include a structure that is depicted in FIG. 8. In this manner, the error monitoring circuit 176 may include error monitoring circuits 200 (error monitoring circuits 200a, 200b, 200c and 200d, depicted as examples) that each is associated with checking for errors in a different word that is indicated by the data capture circuit 18. For example, the error monitoring circuit 200a performs parity error checks on the word indicated by the DATA[0][15:0] signals, the error monitoring circuit 200b performs parity error checks on the word indicated by the DATA[1][15:0] signals, etc. Furthermore, each error monitoring circuit 200 receives the associated control bit for the associated word. For example, the error monitoring circuit 200a receives the CONTROL[0] signal for the word indicated by the DATA[0][15:0] signals.

The error monitoring circuits 200 are chained together so that if one error monitoring circuit 200 detects a control word, the error monitoring circuit 200 updates its parity information and passes this information onto the other error monitoring circuits 200. Each error monitoring circuit 200 compares the parity information derived from the latest control word with each incoming data word to determine if a parity error has occurred. Each error monitoring circuit 200 indicates the latest parity information, along with possible error status via its output signals. In this manner, the error monitoring circuit 200a generates signals called INT_DATA[0][15:0], the error monitoring 200b generates signals called INT_DATA[1][15:0], etc. The output terminals of the last error monitoring circuit 200d in the chain are connected to D-type flip-flop 202 that delays this signal for the next set of four words to be processed by the error monitoring circuit 176. Furthermore, the CONTROL[3] signal is delayed by a D-type flip flop 204 for delaying the control signal before passing to the error monitoring circuit 200a for the next set of words processed by the circuit 176.

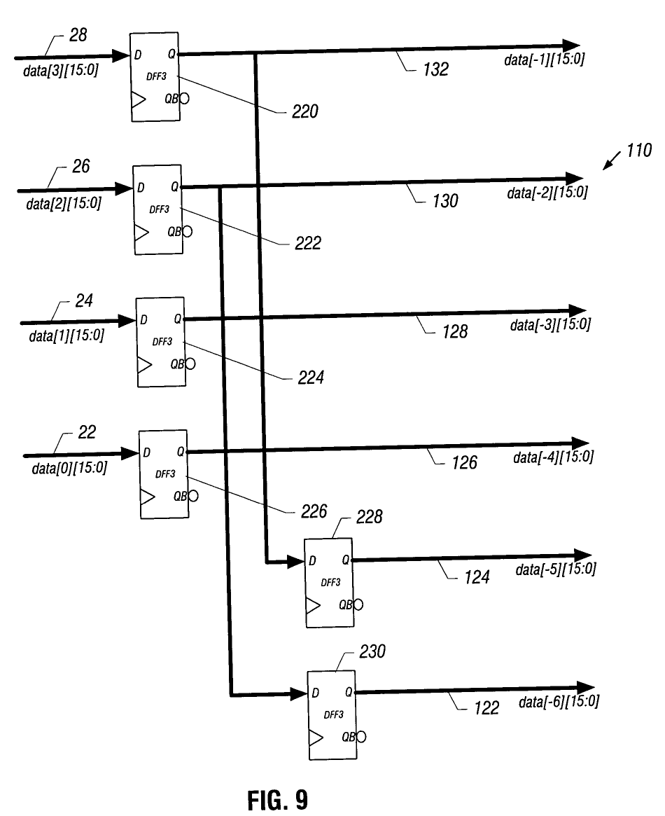

Referring to FIG. 9, in some embodiments of the invention, the data windowing circuit 110 may include four D-type flip-flops 220, 222, 224 and 226 that are coupled to the terminals 28, 26, 24 and 22, respectively. The output terminals of the flip-flop 220 provide the DATA[−1][15:0] signals, the output terminals of the flip-flop 222 provide the DATA[−2][15:0] signals, the output terminals of the flip-flop 224 provide the DATA[−3][15:0] signals and the output terminals of the flip-flop 226 provide the DATA[−4][15:0] signals. For purposes of generating the DATA[−5][15:0] and DATA[−6][15:0] signals, the data windowing circuit 110 includes D-type flip-flops 228 and 230. The flip-flop 228 is coupled to the output terminals of the flip-flop 220 to delay DATA[1][15:0] signals by one CLK clock cycle to produce the DATA[−5][15:0] signals. In a similar manner, the flip-flop 230 has input terminals that are coupled to the output terminals of the flip-flop 222 to delay the DATA[−2][15:0] signals to produce the DATA[−6][15:0] signals.

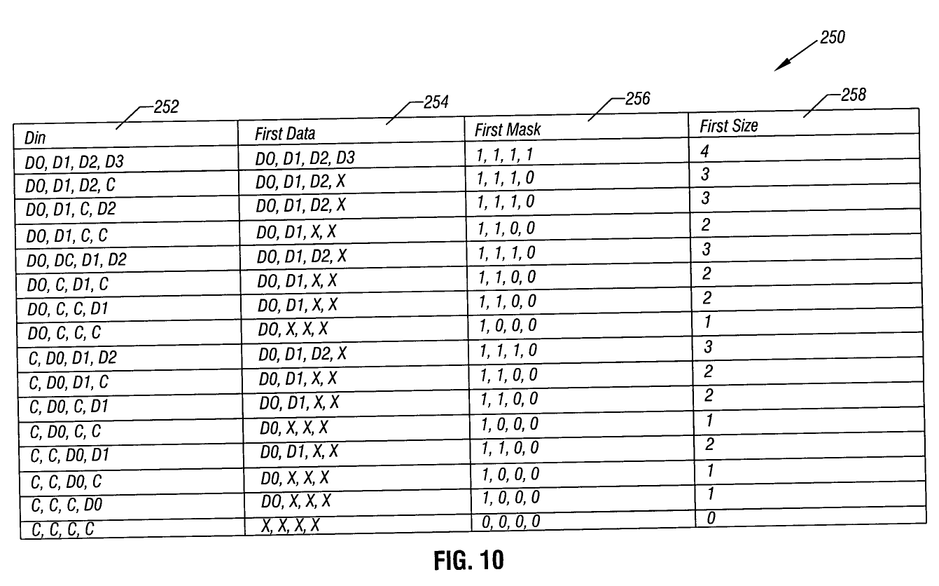

Referring to FIG. 10, in some embodiments of the invention, the operation of the control word filter 162 may be described by a table 250. In this manner, the table 250 includes a first column 252 that represents all of the possible combinations of words that are indicated by the DATA[−2][15:0], DATA[−3][15:0], DATA[−4][15:0] and DATA[−5][15:0] signals. It is noted that these words may be either packet data words or packet control words. The suffix “D” indicates a packet data word, and the suffix “C” indicates a packet control word. For example, in the second row of the table 250 and the first column 252, the first three words are packet data words, and the fourth word is a control word.

Column 256 depicts the filtering that is performed by the control word filter 162. In this manner, the filter 162 produces the output (i.e., the FIRST_MASK[3:0] signals) depicted in column 256 of the table 250 in response to the input word that is depicted in column 252 of the table 250. For example, row 3 of column 252 depicts a sequence in which the two least significant words are data packet words, and the two most significant words are control words. In response to this data, the control word filter 162 produces words D0, D1, X and X, where the “X” represents a don't care condition. Thus, in the preceding example, the FIRST_MASK[3:0] signals that are generated by the control word filter 162 are “1, 1, 0, 0” a state that indicates a masking (as indicated by the “0”) of the two most significant bits. Column 258 of the table 250 depicts a corresponding size indicated by the FIRST_SIZE[2:0] signals. Thus, the preceding example, the corresponding FIRST_SIZE[2:0] signals indicate a “2.” The control word filter 166 operates in a similar manner.

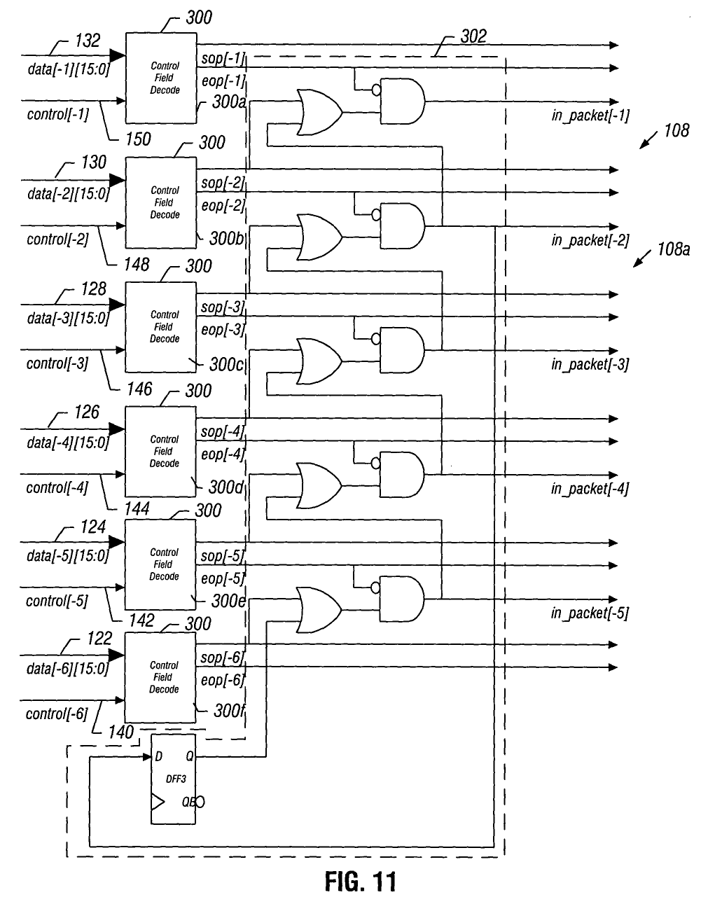

Referring to FIG. 11, in some embodiments of the invention, the control deinterleave logic 108 may include a first section 108a. In this section 108a, the control deinterleave logic 108 includes field decodes circuits 300. Each field decode circuit 300 decodes a particular word to indicate whether the word is an end of packet or a start of packet control word. For example, the field decode circuit 300a receives the DATA[−1][15:0] signals and the CONTROL[−1] signal. In response to these signals, the field decode circuit 300 generates a start-of-packet (SOP[1:0]) signal and an end-of-packet (EOP) signal. If a start of packet or an end of packet control word is found in the word indicated by the DATA[−1][15:0] signals, then the field decode circuit 300 asserts either the SOP signal or the EOP signal to indicate the start of a packet, or the end of a packet, respectively.

The control deinterleave logic 108 also includes, in some embodiments of the invention, logic 302 to indicate whether a particular word is inside a packet. In this manner, the logic 302 furnishes signals called IN_PACKET[−1], IN_PACKET[−2], IN_PACKET[−3], IN_PACKET[−4] and IN_PACKET[−5] to indicate whether a particular word is inside a packet. Generally, a particular word is in a packet if the following logic relationship holds true: the previous word was in a packet; or the previous word was start of packet control word, and the current word is not an end of packet control word.

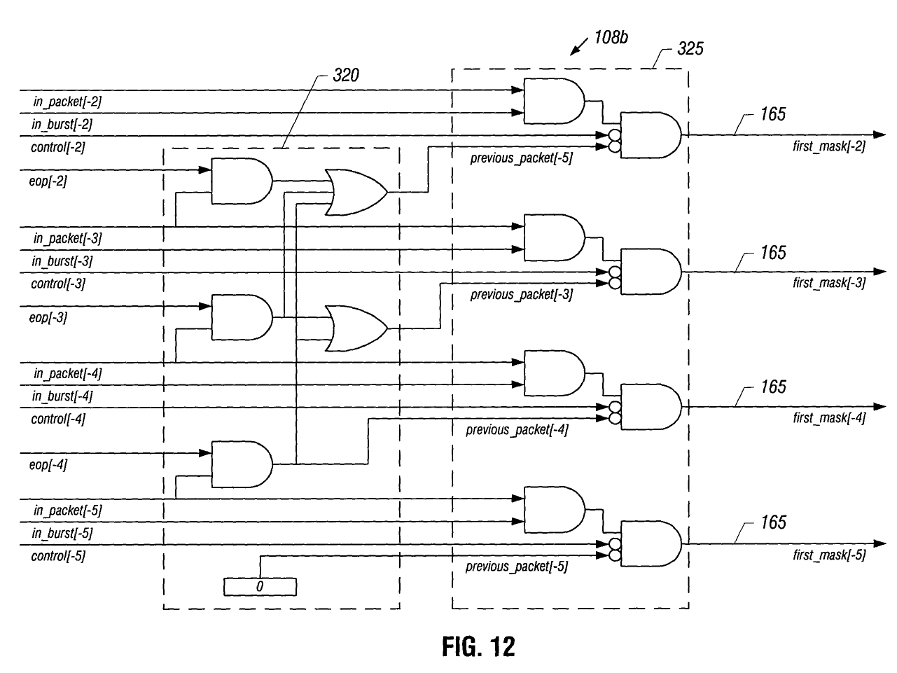

Referring to FIG. 12, in some embodiments of the invention, the control interleave logic 108 also includes a section 108(b) for purposes of generating the FIRST_MASK signals. In this manner, the deinterleave logic 108 includes logic 320 for purposes of generating signals called PREVIOUS_PACKET[−5], PREVIOUS_PACKET[−4], PREVIOUS_PACKET[−3] and PREVIOUS_PACKET[−2]. Any one of these PREVIOUS_PACKET signals goes high for a given word if there has been a previous packet in the current set of input words. Essentially, this is generated by considering if any of the previous words were in the packet and an end of packet state has been reached. The deinterleave logic 108 also includes logic 325 for purposes of determining whether a given word is a data word in the first packet. In this manner, the logic 325 determines if the current word is in the packet in a burst and is not a control word. The logic 325 generates a FIRST_MASK signal.

Thus, to summarize, a high speed packet decoding technique is described herein in which multiple calculations are made on each positive going edge of a lower frequency clock signal. Therefore, in some embodiments of the invention, only one setup clock cycle and one additional clock cycle are incurred, making more time available for logic. In some embodiments of the invention, the combinatorial logic may be designed and verified for operation in a single clock cycle. Additionally, as described above, logic to handle data incoming on multiple clock cycles are constructed by replicating the same combinatorial block multiple times. The above-described arrangement provides a reduction in power consumption, as the D-type flip-flops are synchronized off of a lower clock frequency. There are multiple combinatorial blocks but each one toggles at a fraction of the rate at which the incoming data is received. In some embodiments of the invention, double or quad data rate data may be processed without the need for a multiplied clock. Although, an increased die area may result because multiple combinatorial blocks are reproduced, there is a tradeoff with the advantage of reducing power consumption and processing the incoming data at a higher speed.

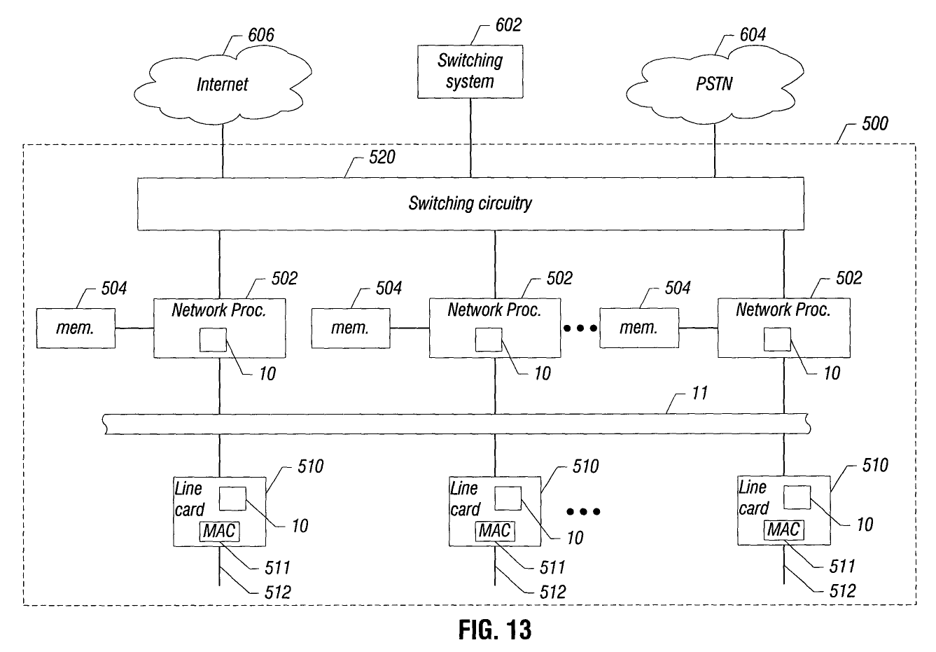

Referring to FIG. 13, in some embodiments of the invention, the packet data recovery system 10 may be used in several different devices of a switching system 500. In this manner, the packet data recovery system 10 may be used in receiving interfaces of devices that are connected to the bus 11. The bus 11 may be an SPI-4 Phase 2 bus to communicate information between link and physical layers of a particular network protocol. For example, in some embodiments of the invention, the switching system 500 may include several network processors 502, each of which may be associated with a particular network protocol. As examples, one network processor 502 may be associated with an Ethernet protocol, another network processor 502 may be associated with a Synchronous Optical NETwork (SONET), etc. The optical Ethernet protocol is described in the Institute of Electrical and Electronics Engineers, Inc. (IEEE) Std. 802.3, 2000 Edition, published on Oct. 20, 2000, and in the IEEE 802.3(a)(e) Supplement, dated Jun. 12, 2002. The SONET standard refers to, for example, the American National Standards Institute (ANSI) T1.105-1995 Synchronous Optical NETwork (SONET) standard, published in 1995.

Each network processor 502 may include a packet data recovery system 10 to capture and identify the content of data that is captured from the bus 11. As an example, each network processor 502 may be coupled to its own associated memory 504, such as a dynamic random access memory (DRAM), for example.

The system 500 may also include, for example, line cards 510, each of which is coupled to the bus 11. Each line card 510 may include, for example, a media access controller (MAC) 511, and each line card 510 may include a packet data recovery system 10 to capture and identify the content of data that is captured from the bus 11. Each line card 510 may be associated with a particular network protocol such as an Ethernet or an SONET protocol, for example; and each line card 510 may be coupled to a network line 512 that is also associated with this network protocol.

Among its other features, the switching system 500 may include a switching circuit 520 that is coupled to the network processors 502. As an example, the switching circuitry 520 may communicate packets between the network processors 502 and circuitry external to the switching system 500, such as another switching system 602, a Public Switching Telephone Network (PSTN) 604 and devices of the Internet 606, as just a few examples.

While the present invention has been described with respect to a limited number of embodiments, those skilled in the art, having the benefit of this disclosure, will appreciate numerous modifications and variations therefrom. It is intended that the appended claims cover all such modifications and variations as fall within the true spirit and scope of this present invention.

What is claimed is:

1. A method comprising:
receiving data units from a bus, each data unit being received from the bus at a different time; and
for each data unit, concurrently generating a first indication of a content of said each data unit and a second indication of a content of one of the data units received from the bus prior to said each data unit.

2. The method of claim 1, wherein the generating comprises:
providing the first indication in response to an edge of a clock signal; and
providing the second indication in response to the edge of the clock signal.

3. The method of claim 1, wherein the first indication identifies a packet content of a subset of said each data unit.

4. The method of claim 3, wherein the first indication identifies a packet content of a subset of said one of the data units received from the bus prior to said each data unit.

5. The method of claim 4, wherein a combined size of the subset of said each data unit and the subset of said one of the data units received from the bus prior to said each data unit is approximately the same size of said each data unit.

6. The method of claim 1, further comprising:
not using any states machines to generate the first indication and the second indication.

7. The method of claim 1, wherein at least one of the first indication and the second indication comprises an indication of packet data and control data.

8. The method of claim 1, wherein the receiving occurs at a first frequency; and
the generating occurs at a second frequency substantially the same as the first frequency.

9. The method of claim 1, wherein at least one of the first indication and the second indication identifies a location of control data.

10. The method of claim 1, wherein at least one of the first indication and the second indication identifies a location of packet content data.

11. The method of claim 1, wherein at least one of the first indication and the second indication identifies a location of an error.

12. The method of claim 1, wherein the bus comprises a multiple-word input bus, and the generating comprises:
routing data from the bus into separate busses, each of separate busses being associated with a different packet.

13. The method of claim 1, further comprising:
replicating combinatorial blocks to process the data units, each combinatorial block being associated with the processing of one or more of the data units.

14. The method of claim 1, wherein the data units are received from the bus in synchronization with a first clock signal and the generating occurs in synchronization with a second clock signal, wherein the second clock signal has approximately the same frequency as the first clock signal.

15. A system comprising:
a first circuit to receive data units from a bus, each data unit being received from the bus at a different time; and
a second circuit to for each data unit, concurrently generate a first indication of a packet content of said each data unit and a second indication of a packet content of one of the data units received from the bus prior to said each data unit.

16. The system of claim 15, wherein the second circuit provides the first indication in response to an edge of a clock signal and provides the second indication in response to the edge of the clock signal.

17. The system of claim 15, wherein the first indication identifies a packet content of a subset of said each data unit.

18. The system of claim 17, wherein the first indication identifies a packet content of a subset of said one of the data units received from the bus prior to said each data unit.

19. The system of claim 18, wherein a combined size of the subset of said each data unit and the subset of said one of the data units received from the bus prior to said each data unit is approximately the same size of said each data unit.

20. The system of claim 15, wherein the second circuit does not include any state machines to generate the first indication and the second indication.

21. The system of claim 15, wherein at least one of the first indication and the second indication comprises indications of packet content data and control data.

22. The system of claim 15, wherein
the first circuit receives the data units at a first frequency, and
the second circuit generate the first indication and the second indication at a second frequency substantially the same as the first frequency.

23. The system of claim 15, wherein at least one of the first indication and the second indication identifies a location of control data.

24. The system of claim 15, wherein at least one of the first indication and the second indication identifies a location of packet content data.

25. The system of claim 15, wherein at least one of the first indication and the second indication identifies a location of an error.

26. A method comprising:
receiving data units from a bus, each data unit being received from the bus at a different time; and
for each data unit, concurrently responding to portions of at least two of the data units to generate an indication of data content.

27. The method of claim 26, wherein the indication of data content identifies at least one of packet data control data and an error.

28. The method of claim 26, wherein the indication of the data content identifies content from said at least two data units.

29. A system comprising:
a circuit to:
receive data units from a bus, each data unit being received from the bus at a different time, and
for each data unit, concurrently respond to portions of at least two of the data units to generate an indication of data content.

30. The system of claim 29, wherein the indication of data content identifies at least one of packet data control data and an error.

31. The system of claim 29, wherein the indication of the data content identifies content from said at least two data units.

32. A system comprising:
a bus to communicate data units between link and physical layers of a network protocol; and
a circuit to:
receive data units from a bus, each data unit being received from the bus at a different time, and
for each data unit, concurrently respond to portions of at least two of the data units to generate an indication of data content.

33. The system of claim 32, wherein the indication of data content identifies at least one of packet data control data and an error.
